(19) United States
(12) Patent Application Publication
(10) Pub. No.: US 2016/0093821 A1
(43) Pub. Date: Mar. 31, 2016

(54) ORGANIC LIGHT EMITTING DEVICE

(71) Applicants: Cambridge Display Technology Limited, Godmanchester (GB); Sumitomo Chemical Company Limited, Tokyo (JP)

(72) Inventor: Robert Archer, Godmanchester (GB)

(73) Assignees: Cambridge Display Technology Limited, Godmanchester (GB); Sumitomo Chemical Company Limited, Tokyo (JP)

(21) Appl. No.: 14/864,568

(22) Filed: Sep. 24, 2015

(30) Foreign Application Priority Data
Sep. 30, 2014 (GB) 1417255.5

(51) Int. Cl. H01L 51/50; H01L 51/56; H01L 51/52

(52) U.S. Cl. CPC H01L 51/5004; H01L 51/5206; H01L 51/5016; H01L 51/5064; H01L 51/5221; H01L 51/5096; H01L 51/5088; H01L 51/56; H01L 2251/558; H01L 51/0085

(57) ABSTRACT

An organic light-emitting device comprising an anode (103); a cathode (111); a light-emitting layer (109) comprising a first light-emitting material between the anode and the cathode; a first hole-transporting layer (105) comprising a first hole-transporting material between the anode and the light-emitting layer; and a second hole-transporting layer (107) comprising a second hole-transporting material between the first hole-transporting layer and the light-emitting layer, wherein a HOMO level of the first light-emitting material is closer to vacuum than a HOMO level of at least one of the first and second hole-transporting materials.

### RELATED APPLICATIONS

This application claims the benefits under 35 U.S.C. §119(a)-(d) or 35 U.S.C. §365(b) of British application number 1417255.5, filed Sep. 30, 2014, the entirety of which is incorporated herein.

### BACKGROUND OF THE INVENTION

Electronic devices containing active organic materials are attracting increasing attention for use in devices such as organic light emitting diodes (OLEDs), organic photoresponsive devices (in particular organic photovoltaic devices and organic photosensors), organic transistors and memory array devices. Devices containing active organic materials offer benefits such as low weight, low power consumption and flexibility. Moreover, use of soluble organic materials allows use of solution processing in device manufacture, for example inkjet printing or spin-coating.

An OLED may comprise a substrate carrying an anode, a cathode and one or more organic light-emitting layers between the anode and cathode.

Holes are injected into the device through the anode and electrons are injected through the cathode during operation of the device. Holes in the highest occupied molecular orbital (HOMO) and electrons in the lowest unoccupied molecular orbital (LUMO) of a light-emitting material combine to form an exciton that releases its energy as light.

A light emitting layer may comprise a semiconducting host material and a light-emitting dopant wherein energy is transferred from the host material to the light-emitting dopant. For example, J. Appl. Phys. 65, 3610, 1989 discloses a host material doped with a fluorescent light-emitting dopant (that is, a light-emitting material in which light is emitted via decay of a singlet exciton).

Phosphorescent dopants are also known (that is, a light-emitting dopant in which light is emitted via decay of a triplet exciton).

WO 2005/059921 discloses an organic light-emitting device comprising a hole-transporting layer and an electroluminescent layer comprising a host material and a phosphorescent material. High triplet energy level hole-transporting materials are disclosed in order to prevent quenching of phosphorescence.

WO 2010/119273 discloses an organic electroluminescent device having first and second electroluminescent layers including an electroluminescent layer comprising a hole-transporting material and an electroluminescent electron trapping material.

### SUMMARY OF THE INVENTION

In a first aspect the invention provides an organic light-emitting device comprising an anode; a cathode; a light-emitting layer comprising a first light-emitting material between the anode and the cathode; a first hole-transporting layer comprising a first hole-transporting material between the anode and the light-emitting layer; and a second hole-transporting layer comprising a second hole-transporting material between the first hole-transporting layer and the light-emitting layer, wherein a HOMO level of the first light-emitting material is closer to vacuum than a HOMO level of at least one of the first and second hole-transporting materials.

In a second aspect the invention provides a method of forming an organic light-emitting device according to the first aspect, the method comprising the steps of forming a first hole-transporting layer over the anode; forming the second hole-transporting layer over the first hole-transporting layer; forming the light-emitting layer over the second hole-transporting layer; and forming the cathode over the light-emitting layer, wherein the first hole-transporting layer, the second hole-transporting layer and the light-emitting layer are each formed by depositing a formulation comprising the material or materials of each said layer and at least one solvent and evaporating the at least one solvent.

In a third aspect the invention provides an organic light-emitting device comprising an anode; a cathode; a first hole-transporting layer between the anode and the cathode; a second hole-transporting layer comprising a hole-blocking light-emitting material between the first hole-transporting layer and the cathode; and a light-emitting layer between the second hole-transporting layer and the cathode.

The device of the third aspect may comprise a first hole-transporting material, a second hole-transporting material and a first light-emitting material as described in the first aspect.

The hole-blocking light-emitting material of the third aspect may be as described with reference to the first aspect.

The device of the third aspect may be formed by a method according to the second aspect.

### DESCRIPTION OF THE DRAWINGS

The invention will now be described in more detail with reference to the drawings in which:

FIG. 1 illustrates schematically an OLED according to an embodiment of the invention;

FIG. 2A illustrates lowest triplet excited state energy levels of materials in a device having a structure as illustrated in FIG. 1;

FIG. 2B illustrates HOMO and LUMO energy levels of materials in a device having a structure as illustrated in FIG. 1;

FIG. 3 is a graph of current density vs. voltage for hole-only devices with and without a hole-blocking light-emitting material;

FIG. 4 is the electroluminescent spectra for a device according to an embodiment of the invention and a comparative device;

FIG. 5 is a graph of current density vs. voltage for a device according to an embodiment of the invention and a comparative device;

FIG. 6 is a graph of Lm/W efficiency vs. voltage for a device according to an embodiment of the invention and a comparative device;

FIG. 7 is a graph of external quantum efficiency vs. current density for a device according to an embodiment of the invention and a comparative device; and

FIG. 8 is a graph of brightness vs. time for a device according to an embodiment of the invention and a comparative device.

### DETAILED DESCRIPTION OF THE INVENTION

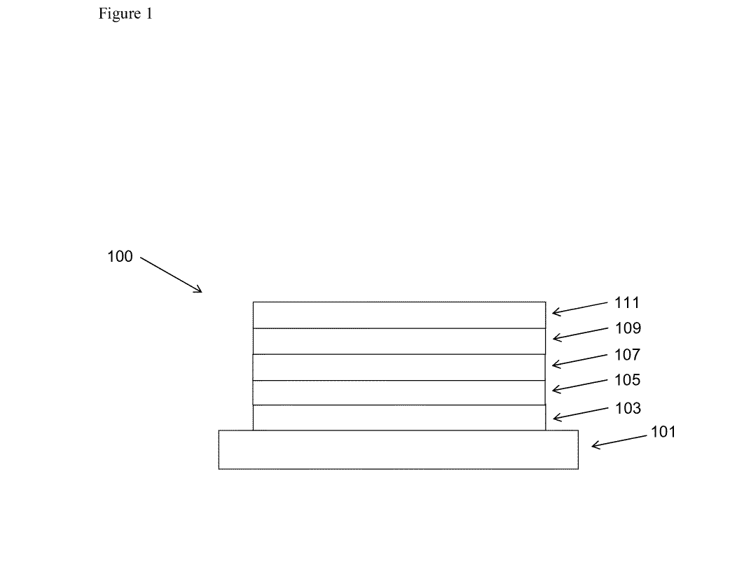

FIG. 1, which is not drawn to any scale, illustrates an OLED 100 according to an embodiment of the invention supported on a substrate 101, for example a glass or plastic substrate. The OLED 100 comprises an anode 103, a first hole-transporting layer 105, a second hole-transporting layer 107, a light-emitting layer 109 and a cathode 111.

The first hole-transporting layer 105 comprises a first hole-transporting material. The hole-transporting layer 105 may consist essentially of the first hole-transporting material or it may contain one or more further materials.

The second hole-transporting layer 107 comprises a second hole-transporting material. The second hole-transporting layer 107 may contain a fluorescent or phosphorescent material which produces light during operation of the device 100 such that the second hole-transporting layer is a second light-emitting layer when the device is in operation. This fluorescent or phosphorescent material may be a hole-blocking material. Preferably, the fluorescent or phosphorescent material of the second hole-transporting layer has a longer peak wavelength than the or each light-emitting material of the light-emitting layer 109. Where present, a light-emitting material of second hole-transporting layer 107 is a red light-emitting material.

Light-emitting layer 109 comprises at least one light-emitting material selected from fluorescent and phosphorescent materials. Preferably, the light-emitting layer 109 comprises one or two light-emitting materials which produce light during operation of the device 100. Light-emitting layer 109 may contain a fluorescent or phosphorescent material having a HOMO level that is closer to vacuum than that of the second hole-transporting material.

Preferably, the or each light-emitting material of the light-emitting layer 109 is a phosphorescent material. The or each phosphorescent material of the light-emitting layer 109 may be doped in a host material, suitably an electron-transporting host material.

In one embodiment, substantially all light is emitting from light-emitting layer 109 when the device is in operation.

In another embodiment, the second hole-transporting layer 107 contains a light-emitting material and substantially all light emitted by the device is from the light-emitting materials of the layers 107 and 109.

Preferably, substantially all light emitted by the device is phosphorescence.

A red light-emitting material may have a photoluminescence spectrum with a peak in the range of about more than 550 up to about 700 nm, optionally in the range of about more than 560 nm or more than 580 nm up to about 630 nm or 650 nm.

A green light-emitting material may have a photoluminescence spectrum with a peak in the range of about more than 490 nm up to about 560 nm, optionally from about 500 nm, 510 nm or 520 nm up to about 560 nm.

A blue light-emitting material may have a photoluminescence spectrum with a peak in the range of up to about 490 nm, optionally about 450-490 nm.

Preferably, the light-emitting layer 109 contains at least one of green and blue light-emitting materials.

The OLED 100 may be a white-emitting OLED. White light may be produced from a combination of red, green and blue light-emitting materials.

White-emitting OLEDs as described herein may have a CIE x coordinate equivalent to that emitted by a black body at a temperature in the range of 2500-9000K and a CIE y coordinate within 0.05 or 0.025 of the CIE y co-ordinate of said light emitted by a black body, optionally a CIE x coordinate equivalent to that emitted by a black body at a temperature in the range of 2700-6000K.

The OLED 100 may contain one or more further layers between the anode 103 and the cathode 111, for example one or more charge-transporting, charge-blocking or charge-injecting layers. Preferably, the device comprises a hole-injection layer between the anode and the hole-transporting layer 105.

Preferably, the first hole-transporting layer 105 is adjacent to the second hole-transporting layer 107.

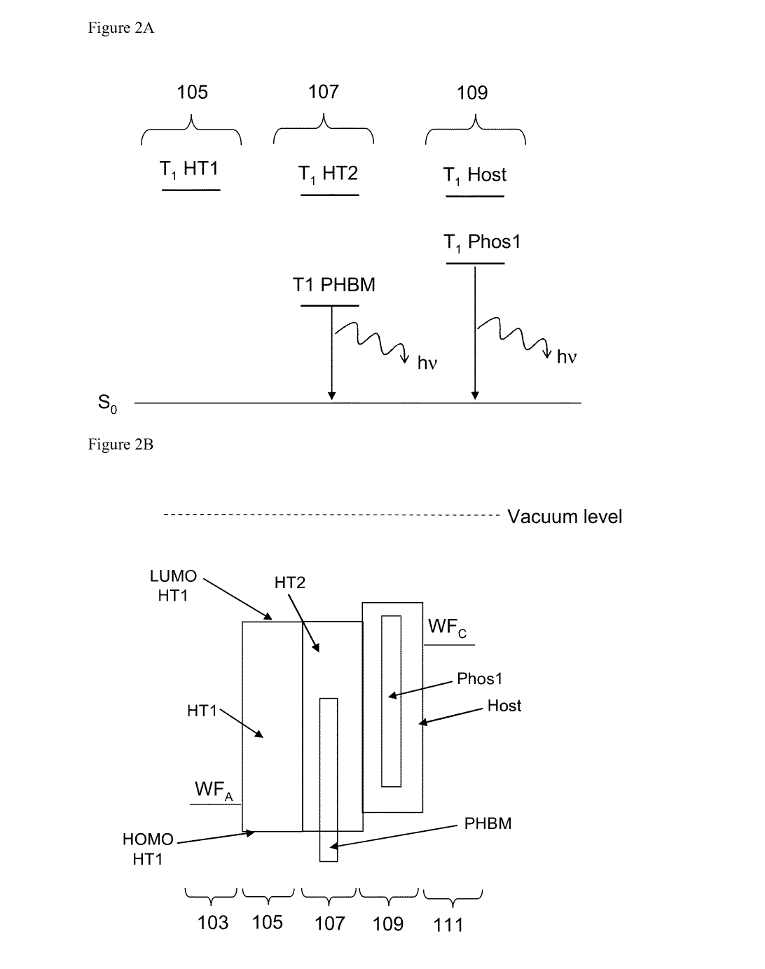

Preferably, the light-emitting layer 109 is adjacent to the second hole-transporting 107. FIG. 2A is a schematic illustration of lowest triplet excited state (T₁) energy levels of a device having the structure of FIG. 1 wherein the first hole-transporting layer 105 contains a first hole-transporting material HT1; the light-emitting layer 107 contains a phosphorescent hole-blocking material PHBM having a relatively long peak wavelength and a second hole-transporting material HT2; and the light-emitting layer 109 contains a host material Host and a phosphorescent light-emitting material Phos1 having a relatively short peak wavelength. The phosphorescent hole-blocking material PHBM may be a red emitting material. The phosphorescent light-emitting material Phos1 may be a green or blue emitting material. In operation, the materials PHBM and Phos1 emit light hν by radiative decay of excitons from T₁ to ground state S₀. In another embodiment (not shown) the phosphorescent hole-blocking material PHBM has a shorter peak wavelength than a phosphorescent light-emitting material in the light-emitting layer 109.

The light-emitting layer may contain a further fluorescent or phosphorescent light-emitting material (not shown) such that the device produces white light.

The triplet energy level of the first hole-transporting material T₁ HT1 in hole-transporting layer 105 is preferably no more than 0.1 eV lower than, and may be the same as or higher than, that of the phosphorescent hole-blocking material T₁ PHBM in the second hole-transporting layer 107 to avoid quenching of phosphorescence from the second hole-transporting layer 107.

The triplet energy level of the second hole-transporting material T₁ HT2 in the second hole-transporting 107 is preferably the same as or higher than that of the phosphorescent hole-blocking material T₁ PHBM in the second hole-transporting layer 107 to avoid quenching of phosphorescence from the second hole-transporting layer 107.

The triplet energy level of the second hole-transporting material T₁ HT2 in the second hole-transporting layer 107 is preferably no more than 0.1 eV lower than, and may be the same as or higher than, that of the phosphorescent material T1 Phos1 in the light-emitting layer 109 to avoid quenching of phosphorescence from Phos1.

In operation, holes are injected from anode 103 into first hole-transporting layer 105, the second hole-transporting layer 107 and light-emitting layer 109.

Electrons are injected from cathode 111 into the light-emitting layer 109 and into the second hole-transporting layer 107.

Holes and electrons recombine in the light-emitting layers of the device to produce excitons that undergo radiative decay to produce fluorescence or phosphorescence. Excitons, in particular triplet excitons, formed in one of the second hole-transporting layer and the light-emitting layers 107 and 109 may migrate into the other of the layers 107 and 109 and may be absorbed by a light-emitting material in that layer.

FIG. 2B is a schematic illustration of HOMO and LUMO energy levels of the device containing materials as described with reference to FIG. 2A. The HOMO-LUMO bandgaps of the materials are shown for each material. For simplicity, only the HOMO and LUMO levels of the first hole-transporting material HT1 have been marked.

The anode 103 has a work function WF_{A}. The cathode 111 has a work function WF_{c}.

The HOMO levels of the first hole-transporting material HT1 of the hole-transporting layer 105 and of the second hole-transporting material HT2 of the second hole-transporting layer 107 are preferably within 0.1 eV of each other to provide a low barrier to hole transport. In FIG. 2B, the HOMO levels of HT1 and HT2 are the same. Optionally, HT1 and HT2 are the same material. If HT1 and HT2 are both polymers containing hole-transporting repeat units then the hole-transporting repeat units may be the same.

The phosphorescent hole-blocking material PHBM of second hole-transporting layer 107 has a HOMO level than is deeper (further from vacuum) than the HOMO of the second hole-transporting material HT2 of second hole-transporting layer 107. Preferably, PHBM has a HOMO level that is at least 0.05 eV, optionally at least 0.1 eV or at least 0.2 eV further from vacuum than that of HT2. This deep HOMO level may limit hole current reaching the light-emitting layer 109. This hole-blocking effect may be mitigated by providing first hole-transporting layer 105 in which no hole-blocking material is present.

As shown in FIG. 2B, PHBM may also have a LUMO level than is deeper (further from vacuum) than the LUMO of the second hole-transporting material HT2. This deep LUMO level may trap electrons in second hole-transporting layer 107, reducing leakage current arising from electrons flowing into first hole-transporting layer 105 as compared to a device in which the electron trapping PHBM light-emitting material is absent.

The hole-blocking light-emitting material of second hole-transporting layer 107 may have a LUMO level that is at least 0.1 eV deeper than, preferably at least 0.2 eV, 0.3 eV, 0.4 eV or 0.5 eV deeper than, the LUMO level of the second hole-transporting material.

Preferably, the hole-blocking light-emitting material of the second hole-transporting layer 107 has a LUMO level that is deeper than, preferably at least 0.1 eV deeper than, the LUMO level of any material in light-emitting layer 109.

First hole-transporting layer 105 and the second hole-transporting layer 107 together preferably have a combined thickness of no more than 50 nm.

The first light-emitting material, illustrated as a phosphorescent light-emitting material Phos1 in FIG. 2B, preferably has a HOMO level than is shallower (closer to vacuum) than the HOMO of the hole-transporting material HT2 of the second hole-transporting layer 105. Preferably, the HOMO of the hole-transporting material HT2 is at least 0.1 eV deeper than the HOMO of the first light-emitting material, and is optionally at least 0.2 eV or 0.3 eV deeper than the HOMO of the first light-emitting material. Optionally, the gap between the HOMO of the first light-emitting material and the second hole-transporting material HT2 is no more than about 1 eV, preferably no more than about 0.5 eV.

### Hole-Transporting Materials

The first and second hole-transporting materials may be non-polymeric or polymeric materials. Preferably, the first and second hole-transporting materials are polymers.

Hole transporting material as described herein may have a LUMO of 2.5 eV or shallower (i.e. closer to vacuum level), optionally 2.2 eV or shallower and a HOMO of 5.5 eV or shallower, preferably 5.3 or 5.2 or shallower. HOMO and LUMO values as described herein are as measured by cyclic voltammetry.

Hole-transporting polymers include conjugated and non-conjugated polymers. A conjugated hole-transporting polymer may comprise repeat units of formula (III):

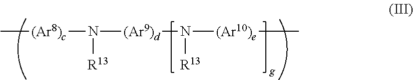

wherein Ar⁸, Ar⁹ and Ar¹⁰ in each occurrence are independently selected from substituted or unsubstituted aryl or heteroaryl, g is 0, 1 or 2, preferably 0 or 1, R¹³ independently in each occurrence is H or a substituent, preferably a substituent, and c, d and e are each independently 1, 2 or 3.

R¹³, which may be the same or different in each occurrence when g is 1 or 2, is preferably selected from the group consisting of alkyl, for example C₁₋₂₀ alkyl, Ar¹¹, a branched or linear chain of Ar¹¹ groups, or a crosslinkable unit that is bound directly to the N atom of formula (III) or spaced apart therefrom by a spacer group, wherein Ar¹¹ in each occurrence is independently optionally substituted aryl or heteroaryl. Exemplary spacer groups are C₁₋₂₀ alkyl, phenyl and phenyl-C₁₋₂₀ alkyl.

Any two aromatic or heteroaromatic groups selected from Ar⁸, Ar⁹, and, if present, Ar¹⁰ and Ar¹¹ directly bound to the same N atom may be linked by a direct bond or a divalent linking atom or group to another of Ar⁸, Ar⁹, Ar¹⁰ and Ar¹¹. Preferred divalent linking atoms and groups include 0, S; substituted N; and substituted C.

Ar⁸ is preferably C₆₋₂₀ aryl, more preferably phenyl, that may be unsubstituted or substituted with one or more substituents.

In the case where g=0, Ar⁹ is preferably C₆₋₂₀ aryl, more preferably phenyl, that may be unsubstituted or substituted with one or more substituents.

In the case where g=1, Ar⁹ is preferably C₆₋₂₀ aryl, more preferably phenyl or a polycyclic aromatic group, for example naphthalene, perylene, anthracene or fluorene, that may be unsubstituted or substituted with one or more substituents.

R¹³ is preferably Ar¹¹ or a branched or linear chain of Ar¹¹ groups. Ar¹¹ in each occurrence is preferably phenyl that may be unsubstituted or substituted with one or more substituents.

Exemplary groups R¹³ include the following, each of which may be unsubstituted or substituted with one or more substituents, and wherein * represents a point of attachment to N:

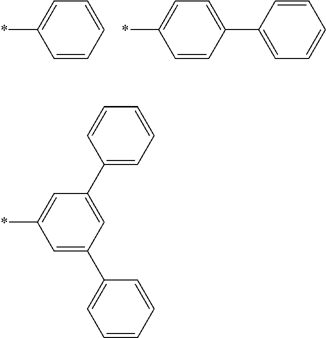

c, d and e are preferably each 1.

Ar⁸, Ar⁹, and, if present, Ar¹⁰ and Ar¹¹ are each independently unsubstituted or substituted with one or more, optionally 1, 2, 3 or 4, substituents. Exemplary substituents may be selected from:
substituted or unsubstituted alkyl, optionally C₁₋₂₀ alkyl, wherein one or more non-adjacent C atoms may be replaced with optionally substituted aryl or heteroaryl (preferably phenyl), O, S, C═O or —COO— and one or more H atoms may be replaced with F; and
a crosslinkable group attached directly to or forming part of Ar⁸, Ar⁹, Ar¹⁰ or Ar¹¹ or spaced apart therefrom by a spacer group, for example a group comprising a double bond such and a vinyl or acrylate group, or a benzocyclobutane group.

Preferred substituents of Ar⁸, Ar⁹, and, if present, Ar¹⁰ and Ar¹¹ are C₁₋₄₀ hydrocarbyl, preferably C₁₋₂₀ alkyl or a hydrocarbyl crosslinking group.

Preferred repeat units of formula (III) include units of formulae 1-3:

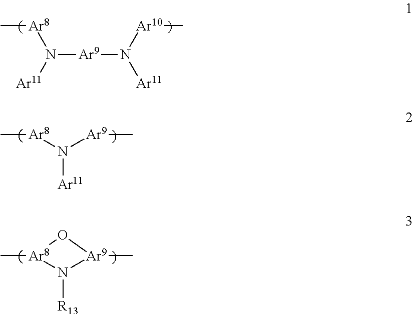

Preferably, Ar⁸, Ar¹⁰ and Ar¹¹ of repeat units of formula 1 are phenyl and Ar⁹ is phenyl or a polycyclic aromatic group.

Preferably, Ar⁸, Ar⁹ and Ar¹¹ of repeat units of formulae 2 and 3 are phenyl.

Preferably, Ar⁸ and Ar⁹ of repeat units of formula 3 are phenyl and R¹¹ is phenyl or a branched or linear chain of phenyl groups.

A hole-transporting polymer comprising repeat units of formula (III) may be a homopolymer or a copolymer containing repeat units of formula (III) and one or more co-repeat units.

In the case of a copolymer, repeat units of formula (III) may be provided in a molar amount in the range of about 10 mol % up to about 95 mol %, optionally about 10-75 mol % or about 10-50 mol %.

Exemplary co-repeat units include arylene repeat units that may be unsubstituted or substituted with one or more substituents, for example one or more C₁₋₄₀ hydrocarbyl groups.

Exemplary arylene co-repeat units include 1,2-, 1,3- and 1,4-phenylene repeat units, 3,6- and 2,7-linked fluorene repeat units, indenofluorene, 1,4-linked naphthalene; 2,6-linked naphthalene, 9,10-linked anthracene; 2,6-linked anthracene; phenanthrene, for example 2,7-linked phenanthrene repeat units, each of which may be unsubstituted or substituted with one or more substituents, for example one or more C₁₋₄₀ hydrocarbyl substituents.

Linking positions and/or substituents of arylene co-repeat units may be used to control the T₁ level of a hole-transporting polymer by controlling the extent of conjugation of the hole-transporting polymer.

Substituents may be provided adjacent to one or both linking positions of an arylene co-repeat unit to create steric hindrance with adjacent repeat units, resulting in twisting of the arylene co-repeat unit out of the plane of the adjacent repeat unit.

A twisting repeat unit may have formula (I):

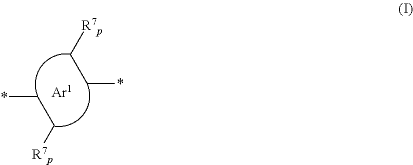

wherein Ar¹ is an arylene group; R⁷ in each occurrence is a substituent; and p is 0 or 1. The one or two substituents R⁷ may be the only substituents of repeat units of formula (I), or one or more further substituents may be present, optionally one or more C₁₋₄₀ hydrocarbyl groups.

The one or two substituents R⁷ adjacent to the linking positions of formula (I) create steric hindrance with one or both repeat units adjacent to the repeat unit of formula (I).

Each R⁷ may independently be selected from the group consisting of:
alkyl, optionally C₁₋₂₀ alkyl, wherein one or more non-adjacent C atoms may be replaced with optionally substituted aryl or heteroaryl, O, S, substituted N, C═O or —COO—, and one or more H atoms may be replaced with F;
aryl and heteroaryl groups that may be unsubstituted or substituted with one or more substituents, preferably phenyl substituted with one or more C₁₋₂₀ alkyl groups;
a linear or branched chain of aryl or heteroaryl groups, each of which groups may independently be substituted, for example a group of formula —(Ar⁷)ᵣ wherein each Ar⁷ is independently an aryl or heteroaryl group and r is at least 2, preferably a branched or linear chain of phenyl groups each of which may be unsubstituted or substituted with one or more C₁₋₂₀ alkyl groups; and
a crosslinkable-group, for example a group comprising a double bond such and a vinyl or acrylate group, or a benzocyclobutane group.

In the case where R⁷ comprises an aryl or heteroaryl group, or a linear or branched chain of aryl or heteroaryl groups, the or each aryl or heteroaryl group may be substituted with one or more substituents R⁸ selected from the group consisting of:
alkyl, for example C₁₋₂₀ alkyl, wherein one or more non-adjacent C atoms may be replaced with O, S, substituted N, C═O and —COO— and one or more H atoms of the alkyl group may be replaced with F;
NR⁹₂, OR⁹, SR⁹, SiR⁹₃ and
fluorine, nitro and cyano;
   wherein each R⁹ is independently selected from the group consisting of alkyl, preferably C₁₋₂₀ alkyl; and aryl or heteroaryl, preferably phenyl, optionally substituted with one or more C₁₋₂₀ alkyl groups.

Substituted N, where present, may be —NR⁶— wherein R⁶ is a substituent and is optionally in each occurrence a C₁₋₄₀ hydrocarbyl group, optionally a C₁₋₂₀ alkyl group.

Preferably, each R⁷, where present, is independently selected from C₁₋₄₀ hydrocarbyl, and is more preferably selected from C₁₋₂₀ alkyl; unsubstituted phenyl; phenyl substituted with one or more C₁₋₂₀ alkyl groups; a linear or branched chain of phenyl groups, wherein each phenyl may be unsubstituted or substituted with one or more substituents; and a crosslinkable group.

One preferred class of arylene repeat units is phenylene repeat units, such as phenylene repeat units of formula (VI):

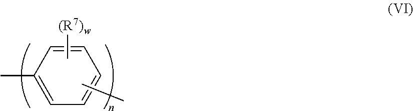

wherein w in each occurrence is independently 0, 1, 2, 3 or 4, optionally 1 or 2; n is 1, 2 or 3; and R⁷ independently in each occurrence is a substituent as described above.

If n is 1 then exemplary repeat units of formula (VI) include the following:

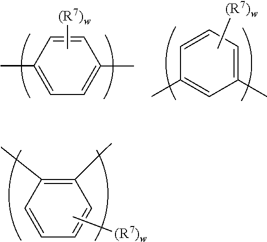

A particularly preferred repeat unit of formula (VI) has formula (VIa):

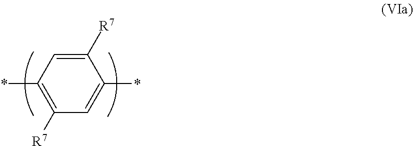

Substituents R⁷ of formula (VIa) are adjacent to linking positions of the repeat unit, which may cause steric hindrance between the repeat unit of formula (VIa) and adjacent repeat units, resulting in the repeat unit of formula (VIa) twisting out of plane relative to one or both adjacent repeat units.

Exemplary repeat units where n is 2 or 3 include the following:

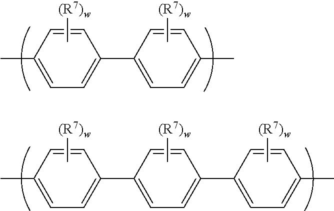

A preferred repeat unit has formula (VIb):

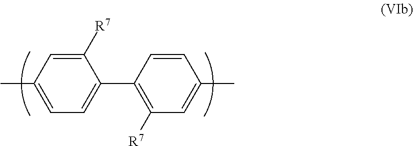

The two R⁷ groups of formula (VIb) may cause steric hindrance between the phenyl rings they are bound to, resulting in twisting of the two phenyl rings relative to one another.

A further class of arylene repeat units is optionally substituted fluorene repeat units, such as repeat units of formula (VII):

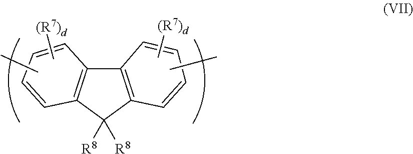

wherein R⁸ in each occurrence is the same or different and is a substituent wherein the two groups R⁸ may be linked to form a ring; R⁷ is a substituent as described above; and d is 0, 1, 2 or 3.

Each R⁸ may independently be selected from the group consisting of:
alkyl, optionally C₁₋₂₀ alkyl, wherein one or more non-adjacent C atoms may be replaced with optionally substituted aryl or heteroaryl, O, S, substituted N, C═O or —COO—, and one or more H atoms may be replaced with F;
aryl and heteroaryl groups that may be unsubstituted or substituted with one or more substituents, preferably phenyl substituted with one or more C₁₋₂₀ alkyl groups;
a linear or branched chain of aryl or heteroaryl groups, each of which groups may independently be substituted, for example a group of formula —(Ar⁷)ᵣ wherein each Ar⁷ is independently an aryl or heteroaryl group and r is at least 2, optionally 2 or 3, preferably a branched or linear chain of phenyl groups each of which may be unsubstituted or substituted with one or more C₁₋₂₀ alkyl groups; and
a crosslinkable-group, for example a group comprising a double bond such and a vinyl or acrylate group, or a benzocyclobutane group.

Preferably, each R⁸ is independently a C₁₋₄₀ hydrocarbyl group.

Substituted N, where present, may be —NR⁶— wherein R⁶ is as described above.

The aromatic carbon atoms of the fluorene repeat unit may be unsubstituted, or may be substituted with one or more substituents R⁷ as described with reference to Formula (VI).

Exemplary substituents R⁷ are alkyl, for example C₁₋₂₀ alkyl, wherein one or more non-adjacent C atoms may be replaced with O, S, C═O and —COO—, optionally substituted aryl, optionally substituted heteroaryl, alkoxy, alkylthio, fluorine, cyano and arylalkyl. Particularly preferred substituents include C₁₋₂₀ alkyl and substituted or unsubstituted aryl, for example phenyl. Optional substituents for the aryl include one or more C₁₋₂₀ alkyl groups.

The extent of conjugation of repeat units of formula (VII) to aryl or heteroaryl groups of adjacent repeat units in the polymer backbone may be controlled by (a) linking the repeat unit through the 3- and/or 6-positions to limit the extent of conjugation across the repeat unit, and/or (b) substituting the repeat unit with one or more substituents R⁸ in or more positions adjacent to the linking positions in order to create a twist with the adjacent repeat unit or units, for example a 2,7-linked fluorene carrying a C₁₋₂₀ alkyl substituent in one or both of the 3- and 6-positions.

The repeat unit of formula (VII) may be a 2,7-linked repeat unit of formula (VIIa):

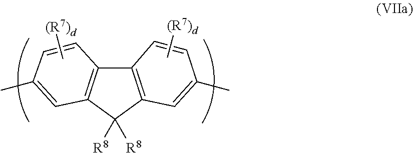

A relatively high degree of conjugation across the repeat unit of formula (VIIa) may be provided in the case where each d=0, or where any substituent R7 is not present at a position adjacent to the linking 2- or 7-positions of formula (VIIa).

A relatively low degree of conjugation across the repeat unit of formula (VIIa) may be provided in the case where at least one d is at least 1, and where at least one substituent R⁷ is present at a position adjacent to the linking 2- or 7-positions of formula (VIIa). Optionally, each d is 1 and the 3- and/or 6-position of the repeat unit of formula (VIIa) is substituted with a substituent R⁷ to provide a relatively low degree of conjugation across the repeat unit.

The repeat unit of formula (VII) may be a 3,6-linked repeat unit of formula (VIIb)

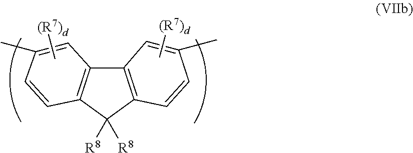

The extent of conjugation across a repeat unit of formula (VIIb) may be relatively low as compared to a corresponding repeat unit of formula (VIIa).

Another exemplary arylene repeat unit has formula (VIII):

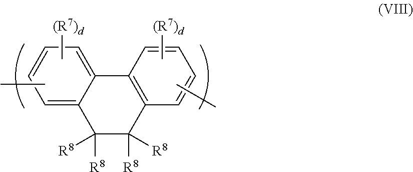

wherein R⁷, R⁸ and d are as described with reference to formula (VI) and (VII) above. Any of the R⁷ groups may be linked to any other of the R⁷ groups to form a ring. The ring so formed may be unsubstituted or may be substituted with one or more substituents, optionally one or more C₁₋₂₀ alkyl groups.

Repeat units of formula (VIII) may have formula (VIIIa) or (VIIIb):

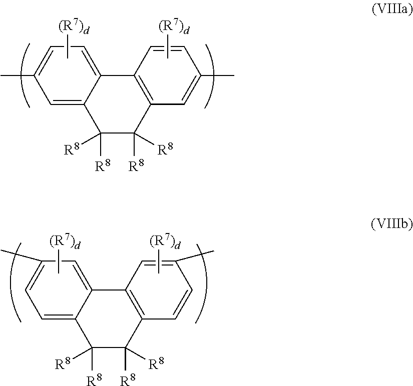

The one or more co-repeat units may include a conjugation-breaking repeat unit, which is a repeat unit that does not provide any conjugation path between repeat units adjacent to the conjugation-breaking repeat unit.

Exemplary conjugation-breaking co-repeat units include co-repeat units of formula (II):

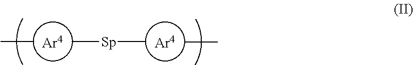

wherein:

Ar⁴ in each occurrence independently represents an aryl or heteroaryl group that may be unsubstituted or substituted with one or more substituents; and

Sp represents a spacer group comprising at least one carbon or silicon atom.

Preferably, the spacer group Sp includes at least one sp³-hybridised carbon atom separating the Ar⁴ groups.

Preferably Ar⁴ is an aryl group and the Ar⁴ groups may be the same or different. More preferably each Ar⁴ is phenyl.

Each Ar⁴ may independently be unsubstituted or may be substituted with 1, 2, 3 or 4 substituents. The one or more substituents may be selected from:
C₁₋₂₀ alkyl wherein one or more non-adjacent C atoms of the alkyl group may be replaced by O, S or COO, C═O, NR⁶ or SiR⁶₂ and one or more H atoms of the C₁₋₂₀ alkyl group may be replaced by F wherein R⁶ is a substituent and is optionally in each occurrence a C₁₋₄₀ hydrocarbyl group, optionally a C₁₋₂₀ alkyl group; and
aryl or heteroaryl, optionally phenyl, that may be unsubstituted or substituted with one or more C₁₋₂₀ alkyl groups.

Preferred substituents of Ar⁴ are C₁₋₂₀ alkyl groups, which may be the same or different in each occurrence.

Exemplary groups Sp include a C₁₋₂₀ alkyl chain wherein one or more non-adjacent C atoms of the chain may be replaced with O, S, —NR⁶—, —SiR⁶₂—, —C(═O)— or —COO— and wherein R⁶ in each occurrence is a substituent and is optionally in each occurrence a C₁₋₄₀ hydrocarbyl group, optionally a C₁₋₂₀ alkyl group.

Exemplary repeat units of formula (II) include the following, wherein R in each occurrence is H or C₁₋₅ alkyl:

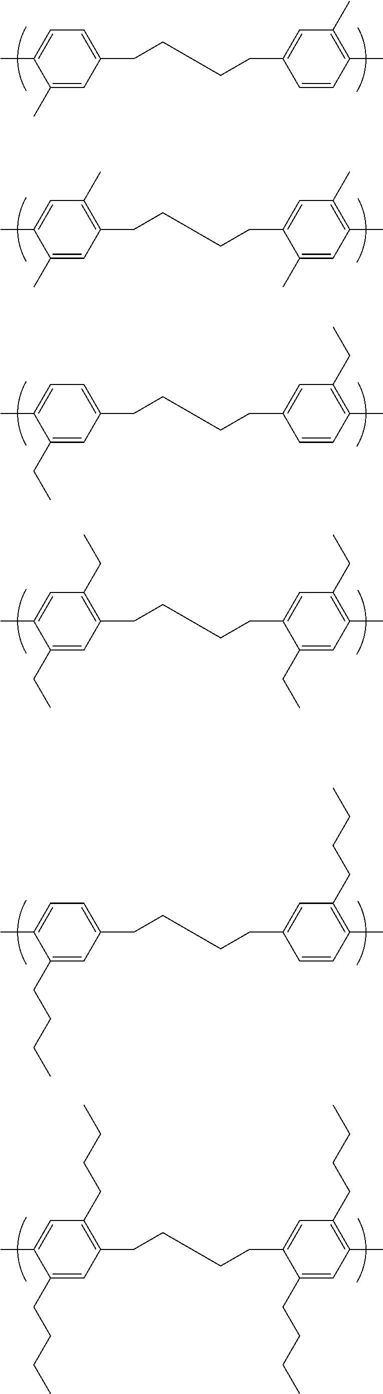

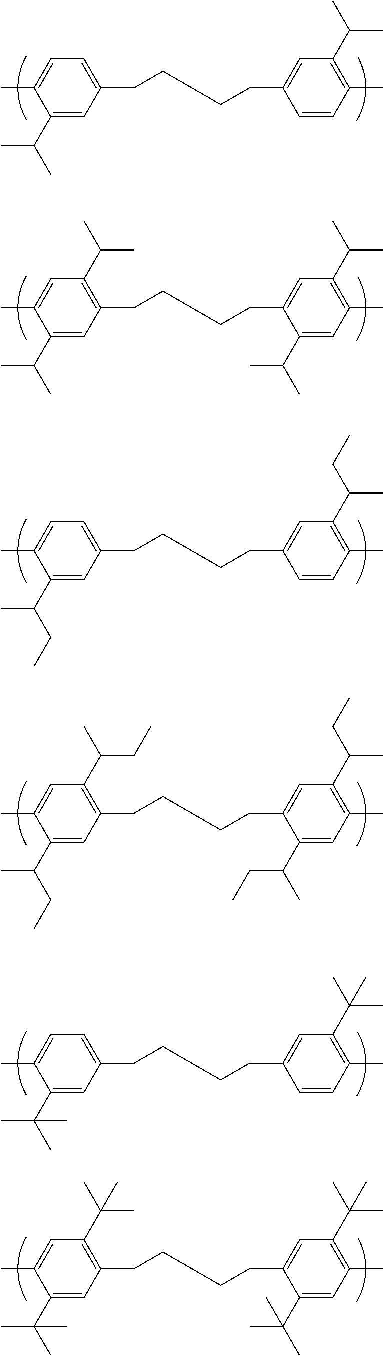

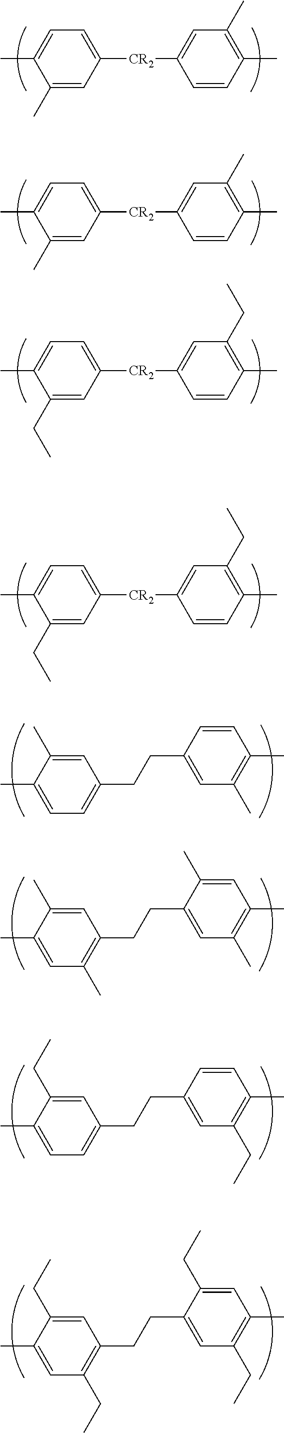

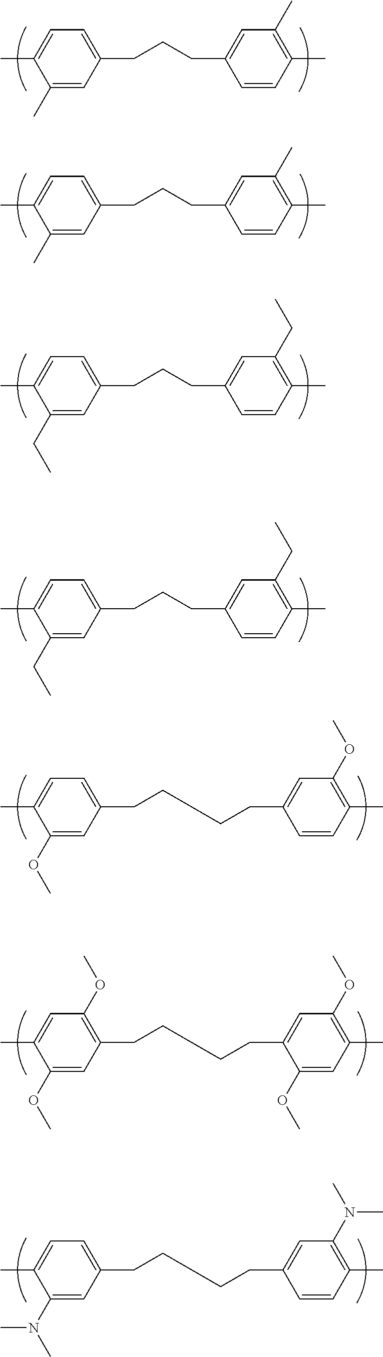

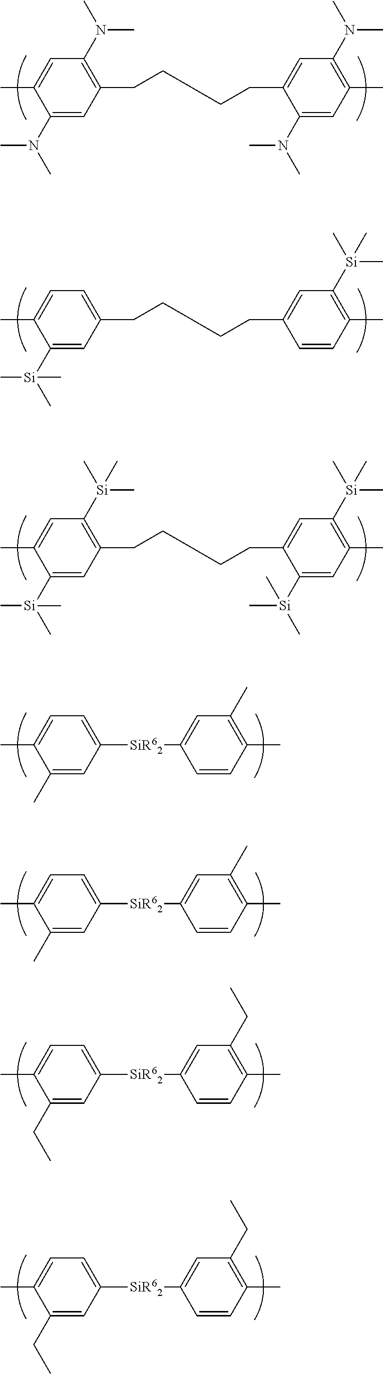

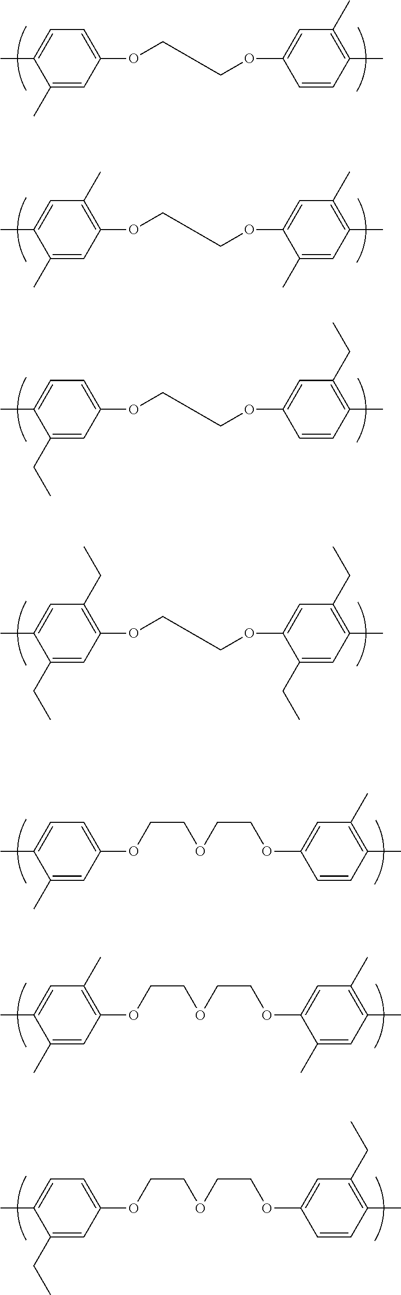

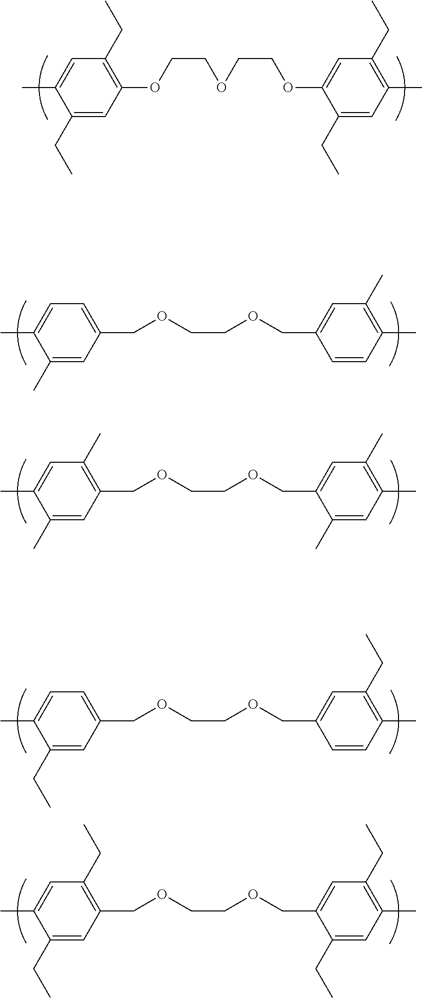

A hole-transporting polymer may contain one, two or more different repeat units of formula (III).

A hole-transporting polymer may contain crosslinkable groups that may be crosslinked following deposition of the hole-transporting polymer to form an insoluble, crosslinked hole-transporting layer prior to formation of the light-emitting layer.

Crosslinkable groups may be provided as substituents of any repeat units of the polymer, for example any of repeat units (I), (II), (III), (VI), (VII) or (VIII) that may be present in the hole-transporting polymer.

Polymers as described herein suitably have a polystyrene-equivalent number-average molecular weight (Mn) measured by gel permeation chromatography in the range of about 1×10³ to 1×10⁸, and preferably 1×10³ to 5×10⁶. The polystyrene-equivalent weight-average molecular weight (Mw) of the polymers described herein may be 1×10³ to 1×10⁸, and preferably 1×10⁴ to 1×10⁷.

The hole-transporting polymers as described anywhere herein are suitably amorphous polymers.

### Light-Emitting Compounds

The hole-blocking light-emitting material of the second hole-transporting layer and the light-emitting material or materials of the light-emitting layer may each independently be fluorescent or phosphorescent materials.

Preferably, the hole-blocking light-emitting material is phosphorescent.

Preferably, the light-emitting layer comprises at least one phosphorescent material.

Preferably, the first light-emitting material is phosphorescent.

Phosphorescent light-emitting materials are preferably phosphorescent transition metal complexes.

Exemplary phosphorescent transition metal complexes have formula (IX):

ML¹_{q}L²ᵣL³ᵣ (IX)

wherein M is a metal; each of L¹, L² and L³ is a coordinating group; q is a positive integer; r and s are each independently 0 or a positive integer; and the sum of (a. q)+(b. r)+(c.s) is equal to the number of coordination sites available on M, wherein a is the number of coordination sites on L¹, b is the number of coordination sites on L² and c is the number of coordination sites on L³. Preferably, a, b and c are each 1 or 2, more preferably 2 (bidentate ligand). In preferred embodiments, q is 2, r is 0 or 1 and s is 0, or q is 3 and r and s are each 0.

Heavy elements M induce strong spin-orbit coupling to allow rapid intersystem crossing and emission from triplet or higher states. Suitable heavy metals M include d-block metals, in particular those in rows 2 and 3 i.e. elements 39 to 48 and 72 to 80, in particular ruthenium, rhodium, palladium, rhenium, osmium, iridium, platinum and gold. Iridium is particularly preferred.

Exemplary ligands L¹, L² and L³ include carbon or nitrogen donors such as porphyrin or bidentate ligands of formula (X):

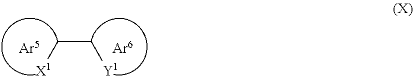

wherein Ar⁵ and Ar⁶ may be the same or different and are independently selected from substituted or unsubstituted aryl or heteroaryl; X¹ and Y¹ may be the same or different and are independently selected from carbon or nitrogen; and Ar⁵ and Ar⁶ may be fused together. Ligands wherein X¹ is carbon and Y¹ is nitrogen are preferred, in particular ligands in which Ar⁵ is a single ring or fused heteroaromatic of N and C atoms only, for example pyridyl or isoquinoline, and Ar⁶ is a single ring or fused aromatic, for example phenyl or naphthyl.

The HOMO and LUMO levels of a light-emitting material may be modified by selection of substituents of the light-emitting material and/or substituent position. HOMO and/or LUMO levels of a material may be deepened (moved further from vacuum) by use of one or more electron-withdrawing substituents, for example one or more substituents having a positive Hammett constant. HOMO and/or LUMO levels of a material may be moved closer to vacuum by use of one or more electron-donating substituents, for example one or more substituents having a negative Hammett constant.

A hole-blocking light-emitting material may be unsubstituted, substituted with one or more electron-withdrawing substituents only or substituted with one or more electron-withdrawing substituents and one or more further substituents, for example one or more C₁₋₄₀ hydrocarbyl groups.

An exemplary hole-blocking light-emitting material has the following structure:

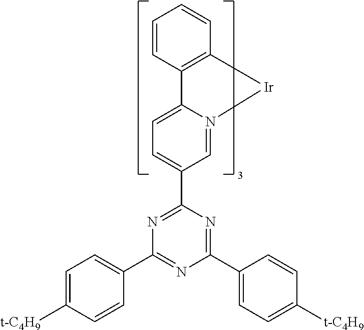

Preferably, the or each light-emitting material of the light-emitting layer has a LUMO level that is closer to vacuum that the LUMO of the hole-blocking light-emitting material, optionally at least 0.1 eV or at least 0.2 eV closer.

Exemplary blue phosphorescent first light-emitting materials having a shallow HOMO level suitable for providing a HOMO level shallower than that of the second hole-transporting material are compounds of formula (X) wherein L¹ is arylimidazole, optionally phenylimidazole, that is unsubstituted or substituted with one or more C₁₋₄₀ hydrocarbyl groups; L¹ is at least 1, preferably 2 or 3; and L² and L³ are each independently 0 or 1, preferably 0.

To achieve red emission, Ar⁵ may be selected from phenyl, fluorene, naphthyl and Ar⁶ are selected from quinoline, isoquinoline, thiophene and benzothiophene.

To achieve green emission, Ar⁵ may be selected from phenyl or fluorene and Ar⁶ may be pyridine.

To achieve blue emission, Ar⁵ may be selected from phenyl and Ar⁶ may be selected from imidazole, pyrazole, triazole and tetrazole.

Examples of bidentate ligands are illustrated below:

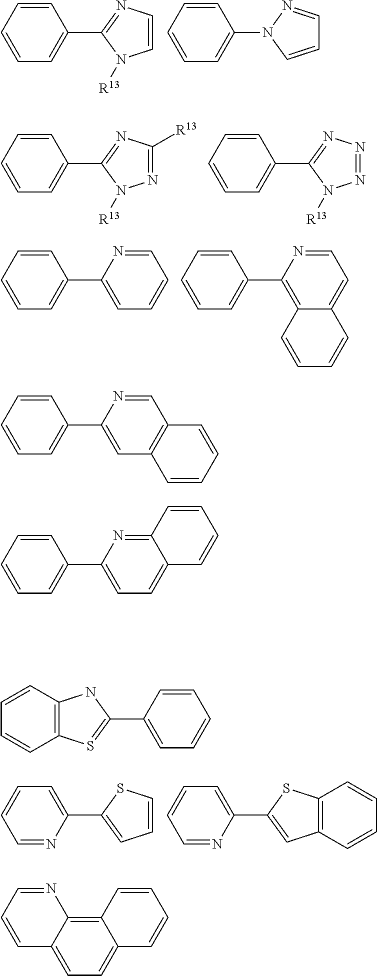

Each of Ar⁵ and Ar⁶ may carry one or more substituents. Two or more of these substituents may be linked to form a ring, for example an aromatic ring.

Other ligands suitable for use with d-block elements include diketonates, in particular acetylacetonate (acac), tetrakis-(pyrazol-1-yl)borate, 2-carboxypyridyl, triarylphosphines and pyridine, each of which may be substituted.

Exemplary substituents include groups R⁷ as described above with reference to Formula (I). Particularly preferred substituents include fluorine or trifluoromethyl which may be used to blue-shift the emission of the complex, for example as disclosed in WO 02/45466, WO 02/44189, US 2002-117662 and US 2002-182441; alkyl or alkoxy groups, for example C₁₋₂₀ alkyl or alkoxy, which may be as disclosed in JP 2002-324679; charge transporting groups, for example carbazole which may be used to assist hole transport to the complex when used as an emissive material, for example as disclosed in WO 02/81448; and dendrons which may be used to obtain or enhance solution processability of the metal complex, for example as disclosed in WO 02/66552. If substituents R⁷ include a charge-transporting group then the compound of formula (IX) may be used in light-emitting layer 107 without a separate host material.

A light-emitting dendrimer comprises a light-emitting core bound to one or more dendrons, wherein each dendron comprises a branching point and two or more dendritic branches. Preferably, the dendron is at least partially conjugated, and at least one of the branching points and dendritic branches comprises an aryl or heteroaryl group, for example a phenyl group. In one arrangement, the branching point group and the branching groups are all phenyl, and each phenyl may independently be substituted with one or more substituents, for example alkyl or alkoxy.

A dendron may have optionally substituted formula (XI)

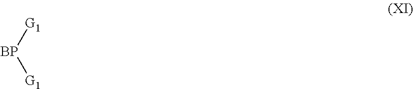

wherein BP represents a branching point for attachment to a core and G₁ represents first generation branching groups.

The dendron may be a first, second, third or higher generation dendron. G₁ may be substituted with two or more second generation branching groups G₂, and so on, as in optionally substituted formula (XIa):

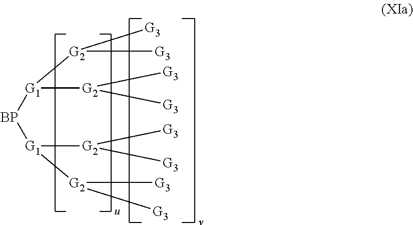

wherein u is 0 or 1; v is 0 if u is 0 or may be 0 or 1 if u is 1; BP represents a branching point for attachment to a core and G₁, G₂ and G₃ represent first, second and third generation dendron branching groups. In one preferred embodiment, each of BP and G₁, G₂ . . . Gₙ is phenyl, and each phenyl BP, G₁, G₂ . . . Gₙ₋₁ is a 3,5-linked phenyl.

In another preferred embodiment, BP is an electron-deficient heteroaryl, for example pyridine, 1,3-diazine, 1,4-diazine, 1,2,4-triazine or 1,3,5-triazine and G₂ . . . Gₙ is an aryl group, optionally phenyl.

Preferred dendrons are a substituted or unsubstituted dendron of formulae (XIb) and (XIc):

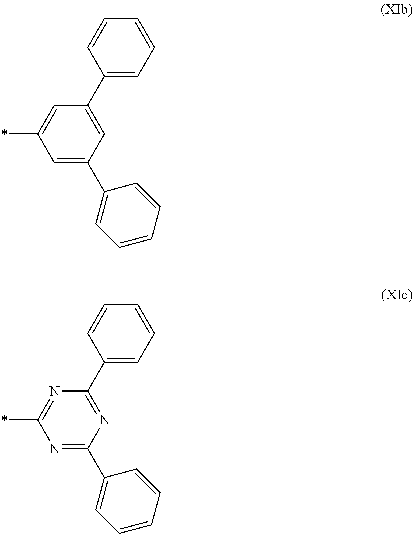 [SMILES: *c1cc(-c2ccccc2)cc(-c2ccccc2)c1 ; *c1nc(-c2ccccc2)nc(-c2ccccc2)n1]

wherein * represents an attachment point of the dendron to a core.

BP and/or any group G may be substituted with one or more substituents, for example one or more C₁₋₂₀ alkyl or alkoxy groups.

The phosphorescent material may be covalently bound to a host material of or may be mixed with a host material.

A phosphorescent hole-blocking material in the second hole-transporting layer may be covalently bound to the second hole-transporting material.

The phosphorescent material may be covalently bound to a host polymer or a hole-transporting polymer as a repeat unit in the polymer backbone, as an end-group of the polymer, or as a side-chain of the polymer. If the phosphorescent material is provided as a side-chain then it may be directly bound to a repeat unit in the backbone of the polymer or it may be spaced apart from the polymer backbone by a spacer group. Exemplary spacer groups include C₁₋₂₀ alkyl and aryl-C₁₋₂₀ alkyl, for example phenyl-C₁₋₂₀ alkyl. One or more carbon atoms of an alkyl group of a spacer group may be replaced with O, S, C═O or COO. A phosphorescent material of a hole-transporting layer or the light-emitting layer 107, and optional spacer, may be provided as a substituent of any of repeat units of formulae (I), (II), (III), (IV), (VI), (VII) or (VIII) described above that may be present in a hole-transporting polymer or host polymer.

Covalent binding of the phosphorescent material to a hole-transporting polymer may reduce or avoid washing of the phosphorescent material out of the hole-transporting layer if an overlying layer is deposited from a formulation of the overlying layer's materials in a solvent or solvent mixture.

A phosphorescent material mixed with a host material or hole-transporting polymer may form 0.1-50 weight %, optionally 0.1-20 wt % of the weight of the components of the layer containing the phosphorescent material

If the phosphorescent material is covalently bound to a hole-transporting polymer then repeat units comprising the phosphorescent material, or an end unit comprising the phosphorescent material, may form 0.1-20 mol %, optionally 0.1-5 mol % of the polymer.

If two or more phosphorescent materials are provided in the light emitting layer 109 then the phosphorescent material with the highest triplet energy level is preferably provided in a larger weight percentage than the lower triplet energy level material or materials.

### Light-Emitting Layer

Light-emitting materials provided in the light-emitting layer 109 may be polymeric or non-polymeric light-emitting materials, and may be fluorescent or phosphorescent light-emitting materials.

A phosphorescent light-emitting layer 109 may contain a host material in addition to at least one phosphorescent light-emitting material. The host material may be a non-polymeric or polymeric material. The host material preferably has a triplet energy level that is the same as or higher than the triplet energy level or levels of the one or more phosphorescent materials.

The host material may be an electron-transporting material to provide for efficient transport of electrons from the cathode into the light-emitting layer 107, either directly if the light-emitting layer 107 is in direct contact with the cathode or, if present, via one or more intervening electron-transporting layers. The host material may have a LUMO level in the range of about 2.8 to 1.6 eV.

Host polymers include polymers having a non-conjugated backbone with charge-transporting groups pendant from the polymer backbone, and polymers having a conjugated backbone in which adjacent repeat units of the polymer backbone are conjugated together. A conjugated host polymer may comprise, without limitation, repeat units selected from optionally substituted arylene or heteroarylene repeat units including any of the arylene (I), (VI), (VII) and (VIII) described above; conjugation-breaking repeat units of formula (II) as described above; and amine repeat units of formula (III) as described above.

The host polymer may contain triazine-containing repeat units. Exemplary triazine-containing repeat units have formula (IV):

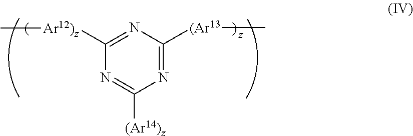

wherein Ar¹², Ar¹³ and Ar¹⁴ are independently selected from substituted or unsubstituted aryl or heteroaryl, and z in each occurrence is independently at least 1, optionally 1, 2 or 3, preferably 1.

Any of Ar¹², Ar¹³ and Ar¹⁴ may be substituted with one or more substituents. Exemplary substituents are substituents R¹⁰, wherein each R¹⁰ may independently be selected from the group consisting of:
substituted or unsubstituted alkyl, optionally C₁₋₂₀ alkyl, wherein one or more non-adjacent C atoms may be replaced with optionally substituted aryl or heteroaryl, O, S, substituted N, C═O or —COO— and one or more H atoms may be replaced with F; and
a crosslinkable group attached directly to Ar¹², Ar¹³ and Ar¹⁴ or spaced apart therefrom by a spacer group, for example a group comprising a double bond such and a vinyl or acrylate group, or a benzocyclobutane group.

Substituted N, where present, may be —NR⁶— wherein R⁶ is a substituent as described above.

Preferably, Ar¹², Ar¹³ and Ar¹⁴ of formula (VIII) are each phenyl, each phenyl independently being unsubstituted or substituted with one or more C₁₋₂₀ alkyl groups.

Ar¹⁴ of formula (IV) is preferably phenyl, and is optionally substituted with one or more C₁₋₂₀ alkyl groups or a crosslinkable unit.

A particularly preferred repeat unit of formula (IV) has formula (IVa), which may be unsubstituted or substituted with one or more substituents R¹⁰, preferably one or more C₁₋₂₀ alkyl groups:

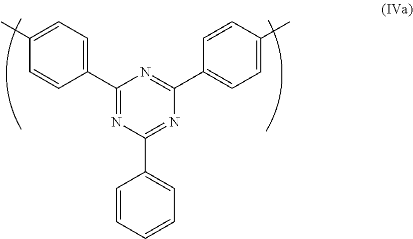

### HOMO and LUMO Level Measurement

HOMO and LUMO levels as described anywhere herein may be measured by cyclic voltammetry.

The working electrode potential may be ramped linearly versus time. When cyclic voltammetry reaches a set potential the working electrode's potential ramp is inverted. This inversion can happen multiple times during a single experiment. The current at the working electrode is plotted versus the applied voltage to give the cyclic voltammogram trace.

Apparatus to measure HOMO or LUMO energy levels by CV may comprise a cell containing a tert-butyl ammonium perchlorate/or tertbutyl ammonium hexafluorophosphate solution in acetonitrile, a glassy carbon working electrode where the sample is coated as a film, a platinum counter electrode (donor or acceptor of electrons) and a reference glass electrode no leak Ag/AgCl. Ferrocene is added in the cell at the end of the experiment for calculation purposes.

Measurement of the difference of potential between Ag/AgCl/ferrocene and sample/ferrocene.

### Method and Settings:

3 mm diameter glassy carbon working electrode
Ag/AgCl/no leak reference electrode
Pt wire auxiliary electrode
0.1 M tetrabutylammonium hexafluorophosphate in acetonitrile
LUMO=4.8−ferrocene (peak to peak maximum average)+onset
Sample: 1 drop of 5 mg/mL in toluene spun at 3000 rpm LUMO (reduction) measurement:

A good reversible reduction event is typically observed for thick films measured at 200 mV/s and a switching potential of −2.5V. The reduction events should be measured and compared over 10 cycles, usually measurements are taken on the 3^{rd} cycle. The onset is taken at the intersection of lines of best fit at the steepest part of the reduction event and the baseline. HOMO and LUMO values may be measured at ambient temperature.

### Hole Injection Layers

A hole injection layer may be provided between the anode 103 and the first hole-transporting layer 105A. The hole-injection layer may be formed from a conductive organic or inorganic material, and may be formed from a degenerate semiconductor.

Examples of conductive organic materials include optionally substituted, doped poly(ethylene dioxythiophene) (PEDT), in particular PEDT doped with a charge-balancing polyacid such as polystyrene sulfonate (PSS) as disclosed in EP 0901176 and EP 0947123, polyacrylic acid or a fluorinated sulfonic acid, for example Nafion®; polyaniline as disclosed in U.S. Pat. No. 5,723,873 and U.S. Pat. No. 5,798,170; and optionally substituted polythiophene or poly(thienothiophene). Examples of conductive inorganic materials include transition metal oxides such as VOx, MoOx and RuOx as disclosed in Journal of Physics D: Applied Physics (1996), 29(11), 2750-2753.

Cathode

The cathode 111 is selected from materials that have a work function allowing injection of electrons into the light-emitting layer 109 of the OLED. Other factors influence the selection of the cathode such as the possibility of adverse interactions between the cathode and the light-emitting material. The cathode may consist of a single material such as a layer of aluminium. Alternatively, it may comprise a plurality of conductive materials such as metals, for example a bilayer of a low work function material and a high work function material such as calcium and aluminium, for example as disclosed in WO 98/10621. The cathode may comprise elemental barium, for example as disclosed in WO 98/57381, Appl. Phys. Lett. 2002, 81(4), 634 and WO 02/84759. The cathode may comprise a thin, preferably 0.5-5 nm, layer of metal compound, in particular an oxide or fluoride of an alkali or alkali earth metal, between the organic layers of the device and one or more conductive cathode layers to assist electron injection, for example lithium fluoride as disclosed in WO 00/48258; barium fluoride as disclosed in Appl. Phys. Lett. 2001, 79(5), 2001; and barium oxide. In order to provide efficient injection of electrons into the device, the cathode preferably has a work function of less than 3.5 eV, more preferably less than 3.2 eV, most preferably less than 3 eV. Work functions of metals can be found in, for example, Michaelson, J. Appl. Phys. 48(11), 4729, 1977.

The cathode may be opaque or transparent. Transparent cathodes are particularly advantageous for active matrix devices because emission through a transparent anode in such devices is at least partially blocked by drive circuitry located underneath the emissive pixels. A transparent cathode comprises a layer of an electron injecting material that is sufficiently thin to be transparent. Typically, the lateral conductivity of this layer will be low as a result of its thinness. In this case, the layer of electron injecting material is used in combination with a thicker layer of transparent conducting material such as indium tin oxide.

It will be appreciated that a transparent cathode device need not have a transparent anode (unless, of course, a fully transparent device is desired), and so the transparent anode used for bottom-emitting devices may be replaced or supplemented with a layer of reflective material such as a layer of aluminium. Examples of transparent cathode devices are disclosed in, for example, GB 2348316.

### Encapsulation

Organic optoelectronic devices tend to be sensitive to moisture and oxygen. Accordingly, the substrate preferably has good barrier properties for prevention of ingress of moisture and oxygen into the device. The substrate is commonly glass, however alternative substrates may be used, in particular where flexibility of the device is desirable. For example, the substrate may comprise one or more plastic layers, for example a substrate of alternating plastic and dielectric barrier layers or a laminate of thin glass and plastic.

The device may be encapsulated with an encapsulant (not shown) to prevent ingress of moisture and oxygen. Suitable encapsulants include a sheet of glass, films having suitable barrier properties such as silicon dioxide, silicon monoxide, silicon nitride or alternating stacks of polymer and dielectric or an airtight container. In the case of a transparent cathode device, a transparent encapsulating layer such as silicon monoxide or silicon dioxide may be deposited to micron levels of thickness, although in one preferred embodiment the thickness of such a layer is in the range of 20-300 nm. A getter material for absorption of any atmospheric moisture and/or oxygen that may permeate through the substrate or encapsulant may be disposed between the substrate and the encapsulant.

### Formulation Processing

A formulation suitable for forming the hole-transporting layers and the light-emitting layer may be formed from the components forming those layers and one or more suitable solvents.

The formulation may be a solution of the components of the layer in question, or may be a dispersion in the one or more solvents in which one or more components are not dissolved. Preferably, the formulation is a solution.

Exemplary solvents include benzenes substituted with one or more substituents selected from C₁₋₁₀ alkyl and C₁₋₁₀ alkoxy groups, for example toluene, xylenes and methylanisoles.

Particularly preferred solution deposition techniques including printing and coating techniques such spin-coating and inkjet printing.

Coating methods are particularly suitable for devices wherein patterning of the light-emitting layer is unnecessary—for example for lighting applications or simple monochrome segmented displays.

Printing methods are particularly suitable for high information content displays, in particular full colour displays. A device may be inkjet printed by providing a patterned layer over the anode and defining wells for printing of one colour (in the case of a monochrome device) or multiple colours (in the case of a multicolour, in particular full colour device). The patterned layer is typically a layer of photoresist that is patterned to define wells as described in, for example, EP 0880303.

As an alternative to wells, the ink may be printed into channels defined within a patterned layer. In particular, the photoresist may be patterned to form channels which, unlike wells, extend over a plurality of pixels and which may be closed or open at the channel ends.

Other solution deposition techniques include dip-coating, slot die coating, roll printing and screen printing.

Preferably one or both of the hole-transporting polymers carries crosslinkable groups that are reacted following deposition of the hole-transporting polymer to form a crosslinked hole-transporting layer. The polymer may be crosslinked by thermal treatment or by irradiation, for example UV irradiation. Thermal crosslinking may be at a temperature in the range of about 80-250° C., optionally about 80-200° C. or about 150-200° C.

### Examples

### Materials

Polymers were formed by Suzuki polymerisation as described in WO 00/53656.

Hole-transporting polymer 1 was formed by polymerisation of monomers for forming 50 mol % of a crosslinkable repeat unit of formula (VIa); 10 mol % of a crosslinkable repeat unit of formula (VIIa); and 40 mol % of a repeat unit of formula (III-1) wherein Ar⁹ is fluorene.

Hole-transporting polymer 2 was formed by polymerisation of monomers for forming 50 mol % of crosslinkable repeat units of formula (VIa); 47 mol % of a repeat unit of formula (III-1) wherein Ar⁹ is fluorene; and 3 mol % of a light-emitting repeat unit formed from Monomer 1:

Hole-transporting polymer 3 was formed by polymerisation of monomers for forming 50 mol % of crosslinkable repeat units of formula (VIa); 49.4 mol % of a repeat unit of formula (III-1) wherein Ar⁹ is fluorene; and 0.6 mol % of a light-emitting repeat unit formed from End-capping group 1:

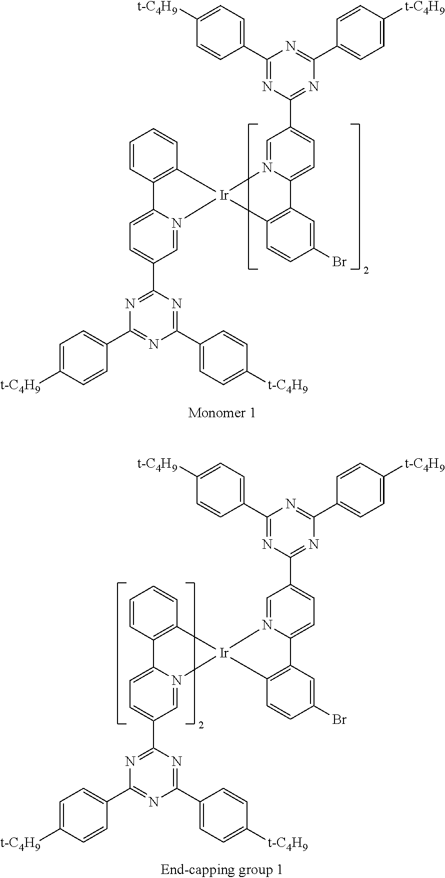

TABLE 1

| | HOMO | LUMO |
|---|---|---|
| Polymer | (eV) | (eV) |
| Hole- | 5.18 | Shallower |
| transporting | | than 1.9 |
| polymer 1 | | |
| Hole- | 5.16 | Shallower |
| transporting | | than 1.9 |
| polymer 2 | | |
| Hole- | 5.16 | Shallower |
| transporting | | than 1.9 |
| polymer 3 | | |

Hole-transporting polymer 1 does not contain a phosphorescent hole-blocking material.

Hole-transporting polymer 2 contains a phosphorescent hole-blocking repeat unit formed by polymerisation of Monomer 1.

Hole-transporting polymer 3 contains a phosphorescent hole-blocking end-group formed by end-capping the polymer with End-capping group 1.

Phosphorescent red-emitting Monomer 1 and End Capping group 1 have a HOMO level of −5.32 eV and a LUMO level of −2.9 eV.

Although the polymers of Table 1 contain a repeat unit or end-group derived from hole-blocking Monomer 1 or End-Capping Group 1, the small amount of this material in the polymer has little or no effect on the HOMO level of the polymer.

### Hole-Only Device

A hole-only device having the following structure was prepared:

### ITO/HIL/HTL/Cathode

wherein ITO is an indium-tin oxide anode; HIL is a hole-injecting layer; and HTL is a hole-transporting layer.

A substrate carrying ITO was cleaned using UV/Ozone. The hole injection layer was formed to a thickness of 65 nm by spin-coating an aqueous formulation of a hole-injection material available from Plextronics, Inc. A hole transporting layer was formed to a thickness of 60 nm by spin-coating Hole-transporting polymer 1, which does not contain a hole-blocking phosphorescent emitter, or Hole-transporting polymer 3 which does contain a hole-blocking phosphorescent emitter. A cathode was formed by evaporation of a first layer of aluminium and a second layer of silver.

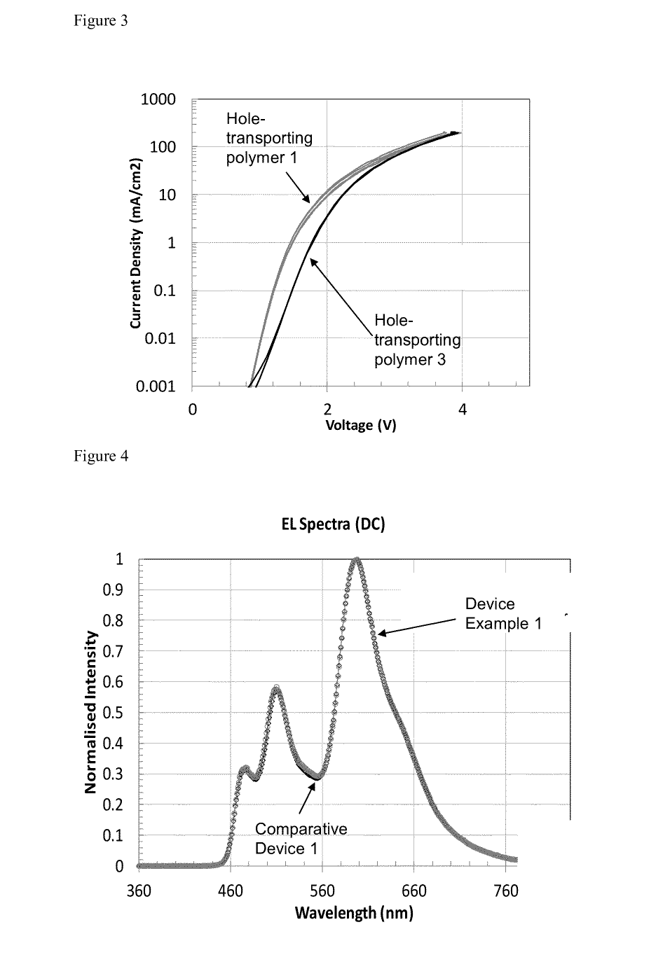

With reference to FIG. 3, current density is higher for the device containing Hole-transporting polymer 1. Without wishing to be bound by any theory, it is believed that hole-blocking by the emitter present in Hole-transporting polymer 3 limits hole current of the device.

### Device Example 1

A white organic light-emitting device having the following structure was prepared:

### ITO/HIL/HTL1/HTL2/LE1/Cathode

wherein ITO is an indium-tin oxide anode; HIL is a hole-injecting layer, HTL1 is a first hole-transporting layer; HTL2 is a second hole-transporting layer comprising a light-emitting, hole-blocking material; and LE1 is a light-emitting layer.

A substrate carrying ITO was cleaned using UV/Ozone. The hole injection layer was formed to a thickness of 65 nm by spin-coating an aqueous formulation of a hole-injection material available from Plextronics, Inc. A first hole transporting layer was formed to a thickness of 10 nm by spin-coating Hole transporting polymer 1 to a thickness of 10 nm and crosslinking the polymer by heating. A second hole-transporting layer was formed to a thickness of 10 nm by spin-coating Hole-transporting polymer 2 to a thickness of 10 nm and crosslinking the polymer by heating. A light-emitting layer was formed to a thickness of 75 nm by spin-coating a composition comprising Host 1 (74 wt %), Blue Phosphorescent Emitter 1 (25 wt %) and Red Phosphorescent Emitter 1 (1 wt %).

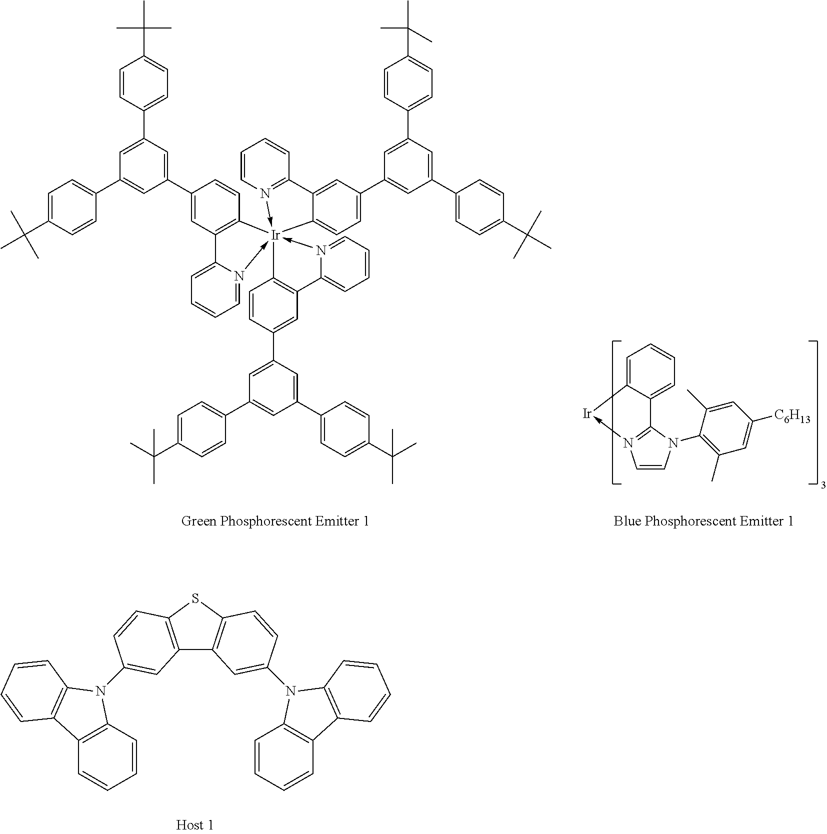

A cathode was formed by evaporation of a first layer of sodium fluoride to a thickness of about 2 nm, a second layer of aluminium to a thickness of about 200 nm and a third layer of silver.

### Comparative Device 1

For the purpose of comparison, a device was formed as described for Device Example 1 except that the 10 nm thick hole-transporting layer of Hole-Transporting Polymer 1 was absent and the 10 nm thick second hole-transporting layer was provided at a thickness of 20 nm rather than 10 nm.

With reference to Table 2, efficiency and colour of Device Example 1 and Comparative Device 1 are similar. CIE x and CIE y values were measured using a Minolta CS200 ChromaMeter.

TABLE 2

| Device | CIE x | CIE y | CRI | CCT | DUV |
|---|---|---|---|---|---|
| Comparative Device 1 | 0.467 | 0.439 | 74.2 | 2696 | 0.010 |
| Device Example 1 | 0.461 | 0.439 | 74.7 | 2736 | 0.010 |

With reference to Table 3, drive voltage is lower and efficiency is higher for Device Example 1 compared to Comparative Device 1.

TABLE 3

| | | | | Efficiency | Efficiency | EQE | |
|---|---|---|---|---|---|---|---|
| | V at | J at | | Lm/W at | Cd/A at | at | Max |
| Device | 1000 cd/m² | 1000 cd/m² | V at 10 ma/cm² | 1000 cd/m² | 1000 cd/m² | 1000 cd/m² | EQE |
| Comparative | 6.7 | 3.7 | 7.6 | 12.7 | 26.9 | 12.2 | 13.8 |
| Device 1 | | | | | | | |
| Device | 5.9 | 3.5 | 6.7 | 15.2 | 29.0 | 13.2 | 15.4 |
| Example 1 | | | | | | | |

With reference to FIG. 4, electroluminescent spectra of Comparative Device 1 and Device Example 1 are very similar.

With reference to FIG. 5, current density at a given voltage for Device Example 1 is similar to or higher than that of Comparative Device 1.

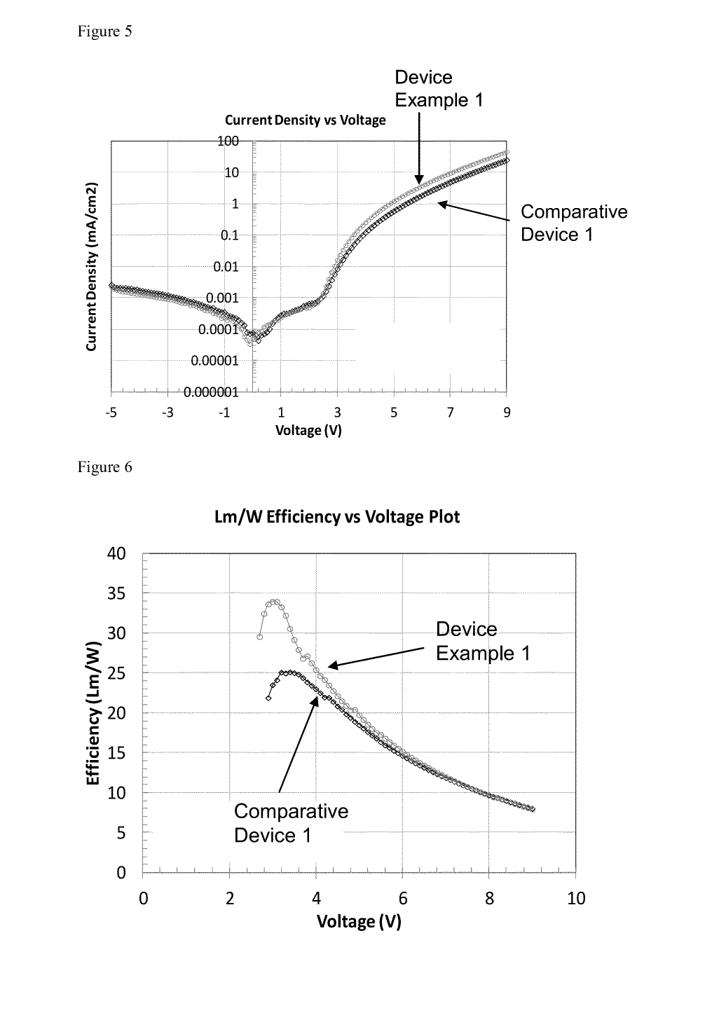

With reference to FIG. 6, lumens per watt efficiency at a given voltage for Device Example 1 is similar to or higher than that of Comparative Device 1.

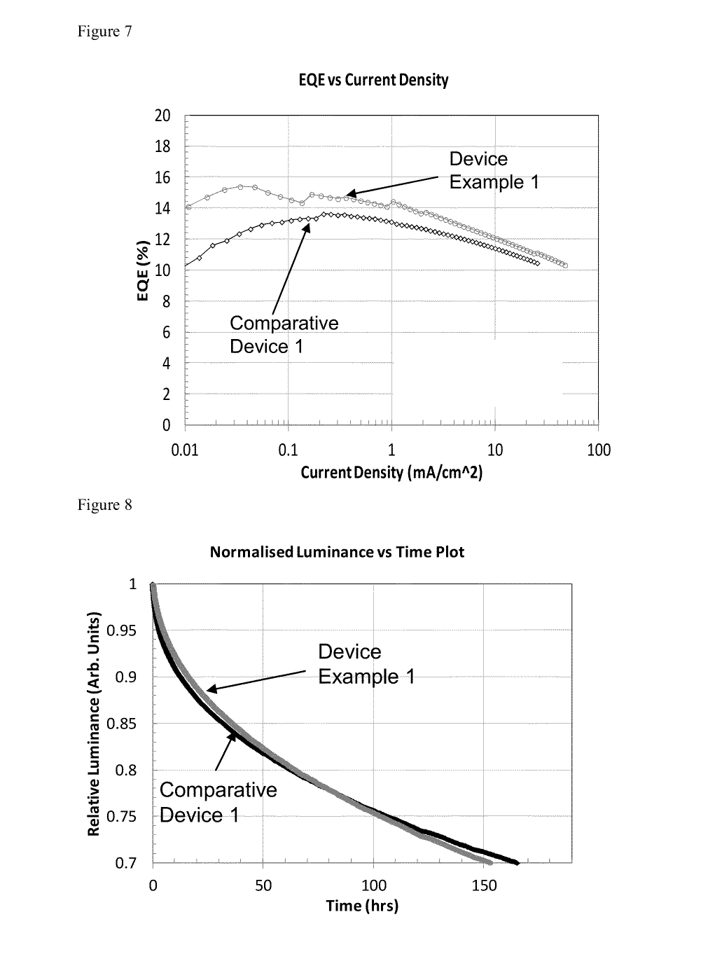

With reference to FIG. 7, external quantum efficiency at a given current density for Device Example 1 is higher than that of Comparative Device 1.

With reference to FIG. 8, the times taken for brightness of Device Example 1 and Comparative Device 1 to fall to 70% of an initial brightness are similar.

Although the present invention has been described in terms of specific exemplary embodiments, it will be appreciated that various modifications, alterations and/or combinations of features disclosed herein will be apparent to those skilled in the art without departing from the scope of the invention as set forth in the following claims.

1. An organic light-emitting device comprising an anode; a cathode; a light-emitting layer comprising a first light-emitting material between the anode and the cathode; a first hole-transporting layer comprising a first hole-transporting material between the anode and the light-emitting layer; and a second hole-transporting layer comprising a second hole-transporting material between the first hole-transporting layer and the light-emitting layer, wherein a HOMO level of the first light-emitting material is closer to vacuum than a HOMO level of at least one of the first and second hole-transporting materials.

2. An organic light-emitting device according to claim 1 wherein the first light-emitting material is a phosphorescent light-emitting material.

3. An organic light-emitting device according to claim 2 wherein the first light-emitting material is a blue phosphorescent light-emitting material.

4. An organic light-emitting device according to claim 1 wherein the second hole-transporting layer comprises a hole-blocking light-emitting material.

5. An organic light-emitting device according to claim 4 wherein a LUMO level of the hole-blocking light-emitting material is at least 0.2 eV further from vacuum than a LUMO level of the second hole-transporting material.

6. An organic light-emitting device according to claim 4 wherein a HOMO level of the hole-blocking light-emitting material is more than 0.1 eV further from vacuum than a HOMO level of the second hole-transporting material.

7. An organic light-emitting device according to claim 4 wherein the hole-blocking light-emitting material is a red light-emitting material.

8. An organic light-emitting device according to claim 1 wherein at least one of the first and second hole-transporting materials is a polymer comprising a repeat unit of formula (III): 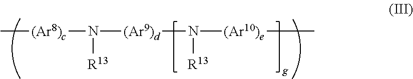
wherein Ar⁸, Ar⁹ and Ar¹⁰ in each occurrence are independently selected from substituted or unsubstituted aryl or heteroaryl, g is 0, 1 or 2, R¹³ is H or a substituent; c, d and e are each independently 1, 2 or 3; and any two aromatic or heteroaromatic groups bound directly to the same N atom may be linked by a direct bond or divalent linking group.

9. An organic light-emitting device according to claim 8 wherein the first and second hole-transporting materials are polymers comprising the same repeat unit of formula (III).

10. An organic light-emitting device according to claim 1 wherein the combined thickness of the first and second hole-transporting layers is no more than 50 nm.

11. An organic light-emitting device according to claim 1 wherein substantially all light emitted from the device is phosphorescence.

12. An organic light-emitting device according to claim 1 wherein the device is a white light-emitting device.

13. An organic light-emitting device according to claim 1 wherein a hole-injection layer is provided between the anode and the first hole-transporting layer.

14. A method of forming an organic light-emitting device according to claim 1 comprising the steps of forming a first hole-transporting layer over the anode;
forming the second hole-transporting layer over the first hole-transporting layer;
forming the light-emitting layer over the second hole-transporting layer; and
forming the cathode over the light-emitting layer, wherein the first hole-transporting layer, the second hole-transporting layer and the light-emitting layer are each formed by depositing a formulation comprising the material or materials of each said layer and at least one solvent and evaporating the at least one solvent.

15. A method according to claim 14 wherein the first hole-transporting layer is crosslinked prior to formation of the second hole-transporting layer.

16. A method according to claim 14 wherein the second hole-transporting layer is crosslinked prior to formation of the light-emitting layer.

17. An organic light-emitting device comprising an anode; a cathode; a first hole-transporting layer between the anode and the cathode; a second hole-transporting layer comprising a hole-blocking light-emitting material between the first hole-transporting layer and the cathode; and a light-emitting layer between the second hole-transporting layer and the cathode.
